(19) United States
(12) Patent Application Publication
(10) Pub. No.: US 2025/0386519 A1
(43) Pub. Date: Dec. 18, 2025

(54) SEMICONDUCTOR ASSEMBLY WITH HEAT SINK STRUCTURE AND METHOD FOR MANUFACTURING THE SAME

(71) Applicant: NANYA TECHNOLOGY CORPORATION, NEW TAIPEI CITY (TW)

(72) Inventors: SHING-YIH SHIH, NEW TAIPEI CITY (TW); TSE-YAO HUANG, NEW TAIPEI CITY (TW)

(21) Appl. No.: 18/765,601

(22) Filed: Jul. 8, 2024

Related U.S. Application Data
(62) Division of application No. 18/746,386, filed on Jun. 18, 2024.

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08146; H01L 2224/80895; H01L 2224/80896; H01L 2225/06541; H01L 2225/06586; H01L 2225/06589; H01L 2924/1431; H01L 2924/1436

(57) ABSTRACT

A semiconductor assembly is provided, which includes a first semiconductor wafer, a memory stack, and a second semiconductor wafer. The memory stack is bonded to the first semiconductor wafer, and the second semiconductor wafer is bonded to the memory stack. The second semiconductor wafer includes a heat sink structure configured to dissipate heat generated by the first semiconductor wafer and the memory stack through a first thermal conductive path and a second thermal conductive path within the semiconductor assembly.

### CROSS-REFERENCE TO RELATED APPLICATION

This application is a divisional application of U.S. Non-Provisional application Ser. No. 18/746,386 filed Jun. 18, 2024, which is incorporated herein by reference in its entirety.

### TECHNICAL FIELD

The present disclosure relates to electronic circuits, and more particularly, to a semiconductor assembly with a heat sink structure and a method for manufacturing the same.

### DISCUSSION OF THE BACKGROUND

The thermal management of 3D stacked chip packages presents challenges, particularly in dissipating heat from the densely stacked chips within the central region. This is especially relevant for 3D stacked integrated circuit (IC) packages, such as those incorporating high bandwidth memory (HBM). Current package-level heat dissipation techniques, including the use of thermal interface materials and cavities between dies, are insufficient for efficiently dissipating the heat generated by the stacked chips in the central region. Additional measures, such as increasing the number of micro bumps, are also ineffective in addressing this issue.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor assembly, which includes a first semiconductor wafer, a memory stack, and a second semiconductor wafer. The memory stack is bonded to the first semiconductor wafer, and the second semiconductor wafer is bonded to the memory stack. The second semiconductor wafer includes a heat sink structure configured to dissipate heat generated by the first semiconductor wafer and the memory stack through a first thermal conductive path and a second thermal conductive path within the semiconductor assembly.

Another aspect of the present disclosure provides a semiconductor assembly, which includes a first semiconductor structure; and a second semiconductor structure, bonded to the first semiconductor structure. The second semiconductor structure comprises a silicon substrate and a plurality of heat dissipating components formed on the silicon substrate to dissipate heat generated by the first semiconductor structure.

Yet another aspect of the present disclosure provides a method, which includes the following steps: providing a first semiconductor wafer, a memory stack, and a second semiconductor wafer; bonding the memory stack to the first semiconductor wafer to form a first semiconductor structure; and bonding the second semiconductor wafer to the first semiconductor structure to form a semiconductor assembly, wherein a first thermal conductive path and a second thermal conductive path are formed within the semiconductor assembly through respective edge regions of the first semiconductor wafer, the memory stack, and the second semiconductor wafer.

The foregoing outlines rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

A more complete understanding of the present disclosure may be derived by referring to the detailed description and claims when considered in connection with the Figures, where like reference numbers refer to similar elements throughout the Figures, and:

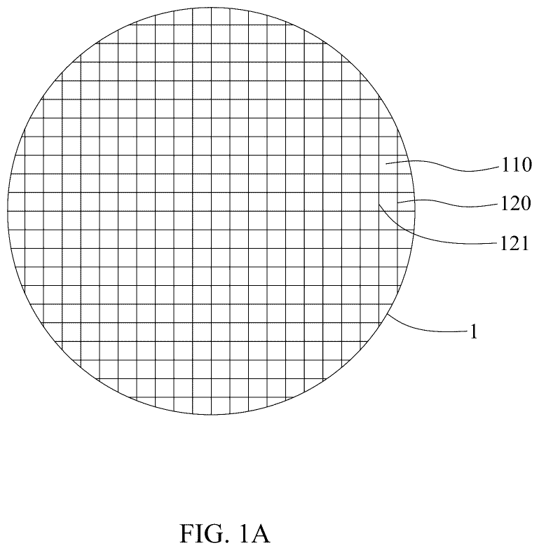

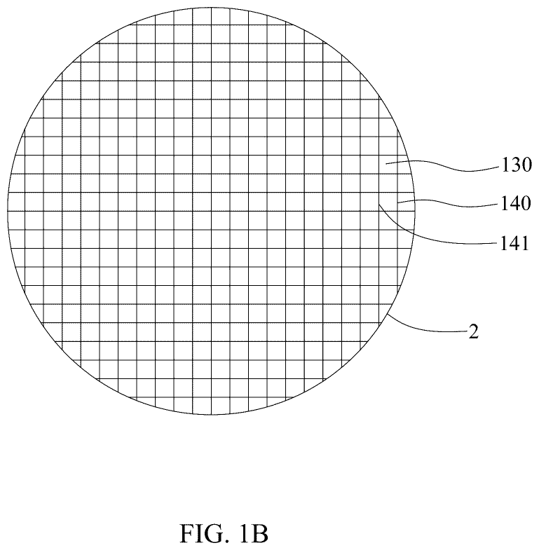

FIGS. 1A and 1B are top views of different wafers in accordance with some embodiments of the present disclosure.

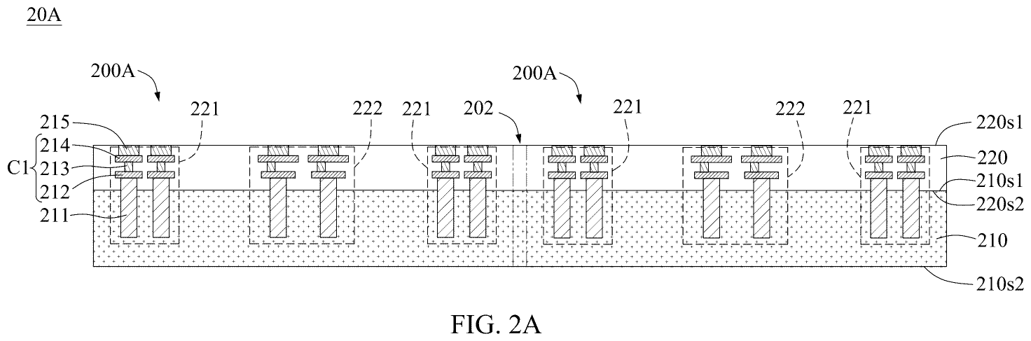

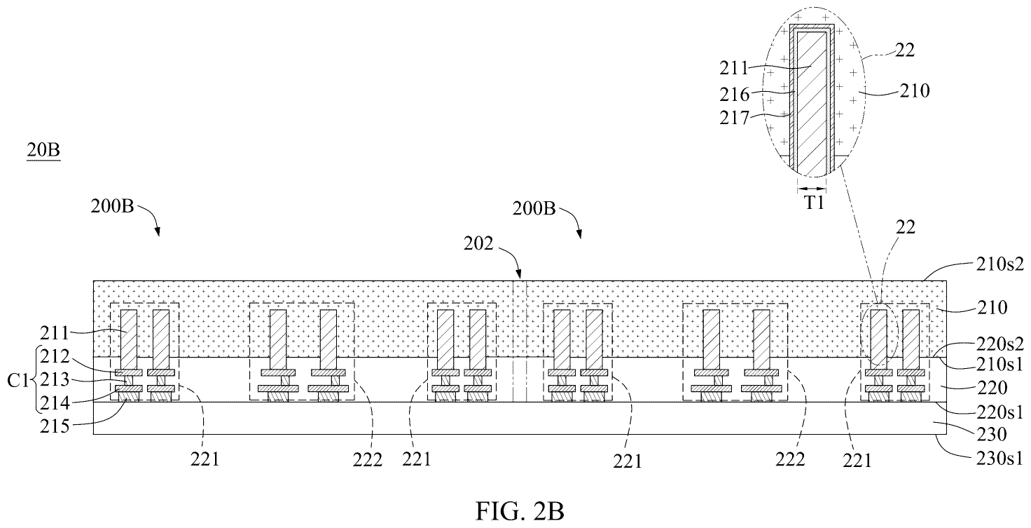

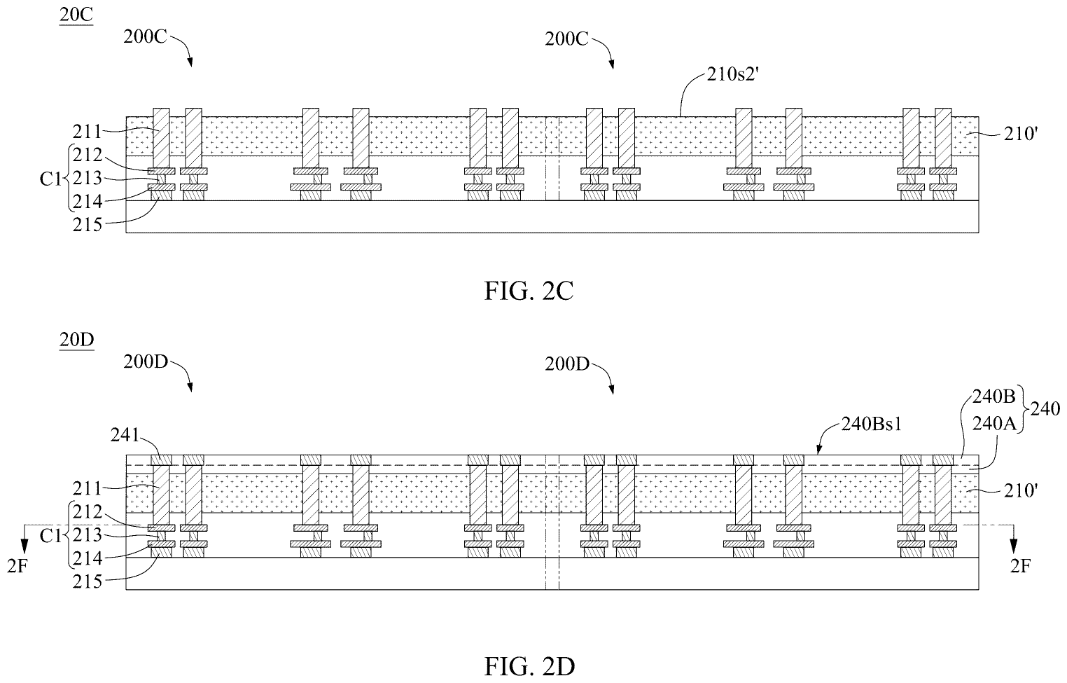

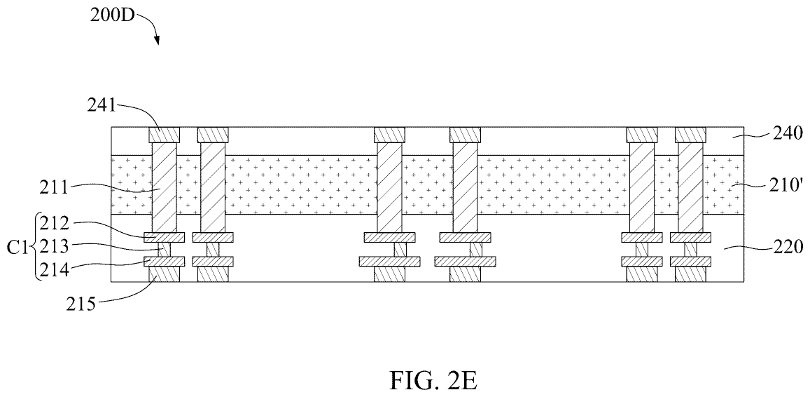

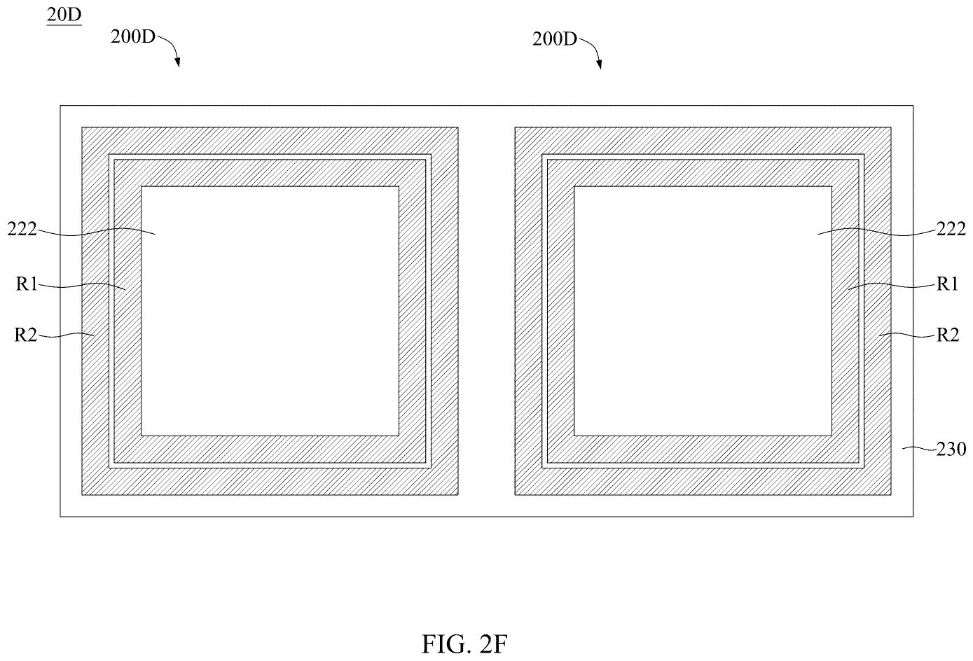

FIGS. 2A-2E are cross sections illustrating respective stages within a manufacturing process of a semiconductor die in accordance with some embodiments of the present disclosure.

FIG. 2F is a top view of the semiconductor structure 20D from line 2F-2F in FIG. 2D.

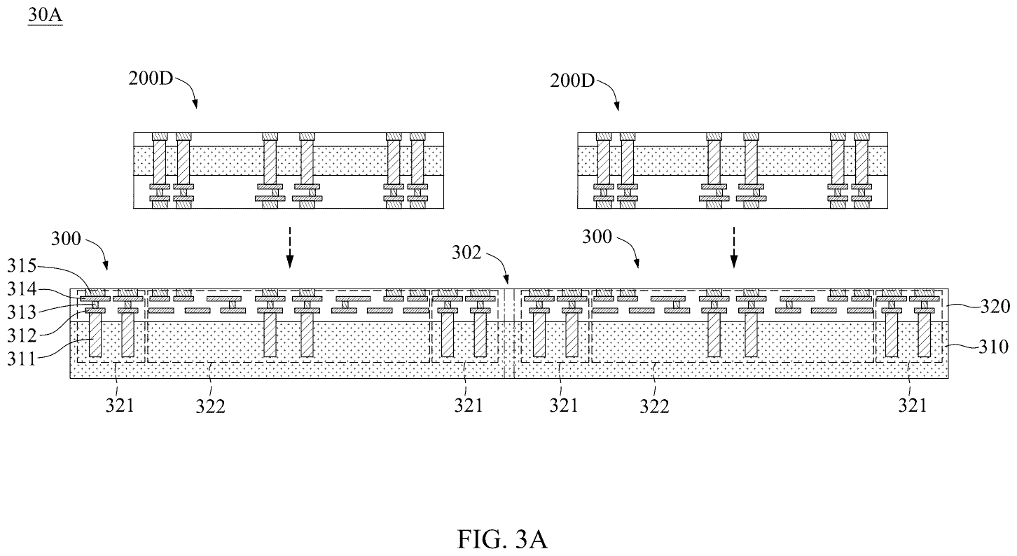

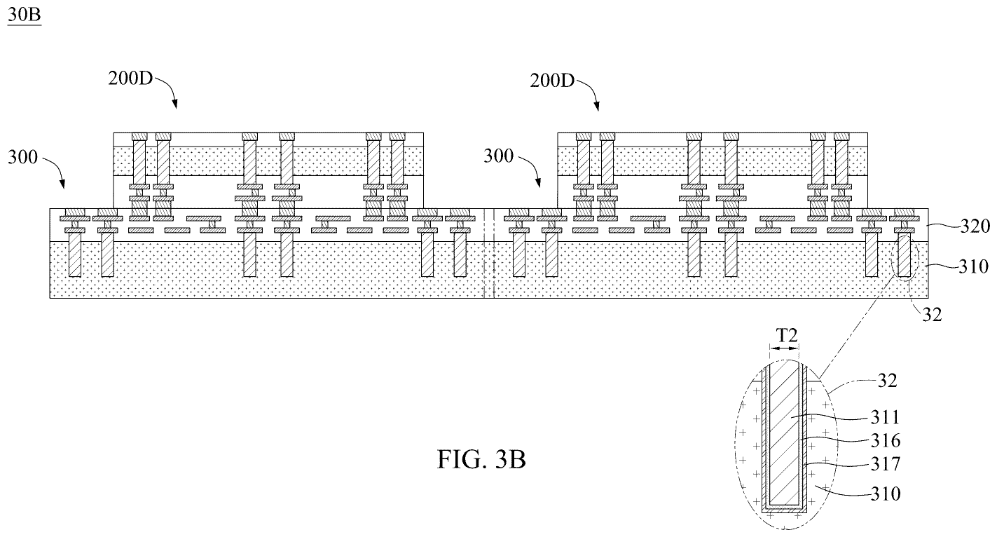

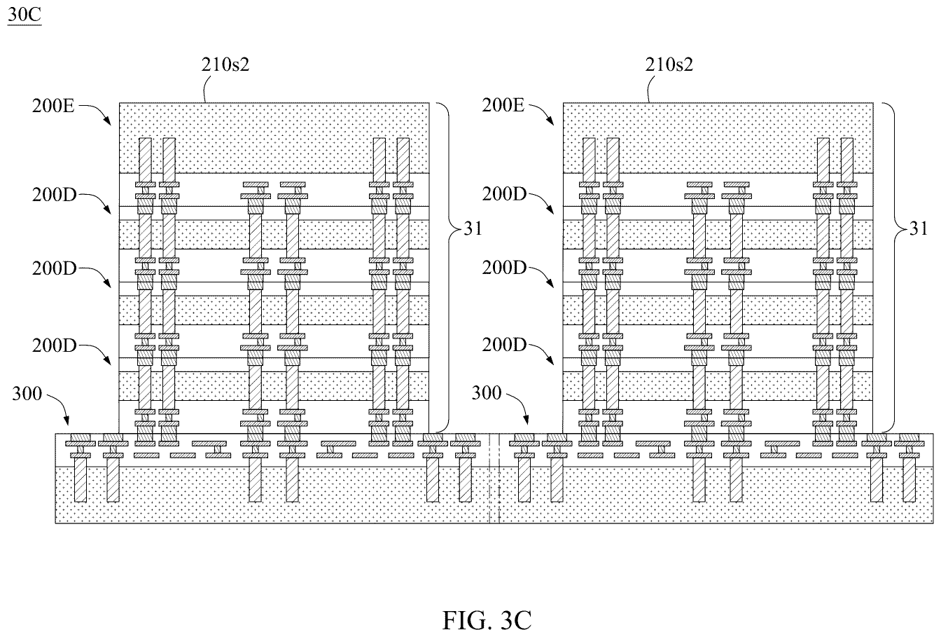

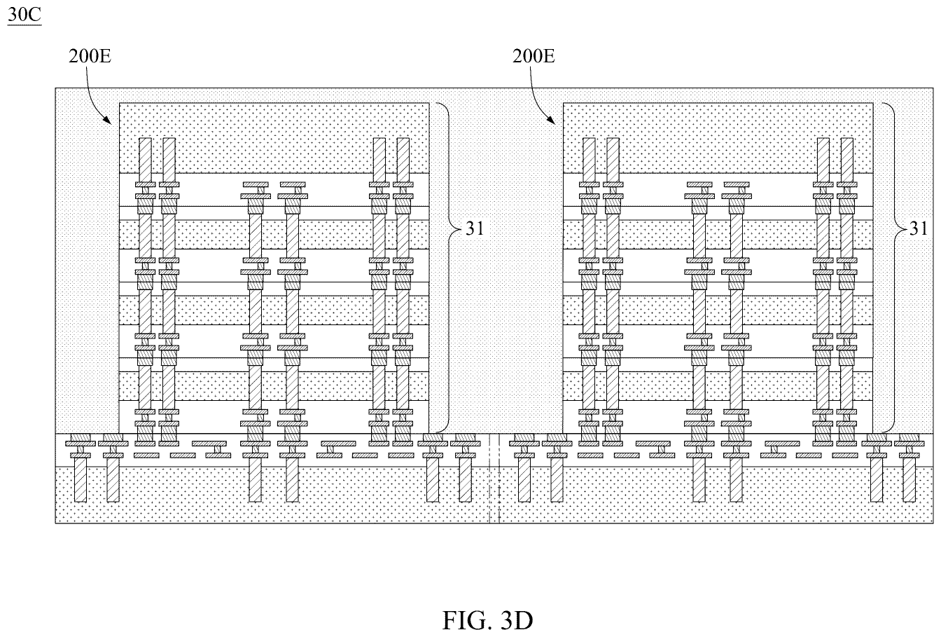

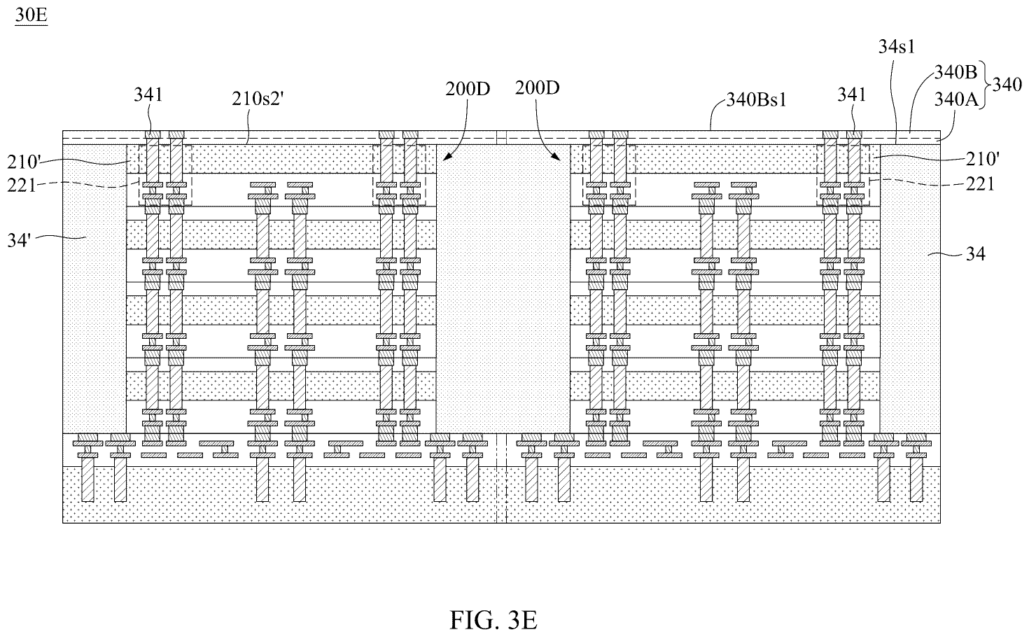

FIGS. 3A-3E are cross sections of semiconductor structures within different stages for forming a 3D stacked IC package in accordance with some embodiments of the present disclosure.

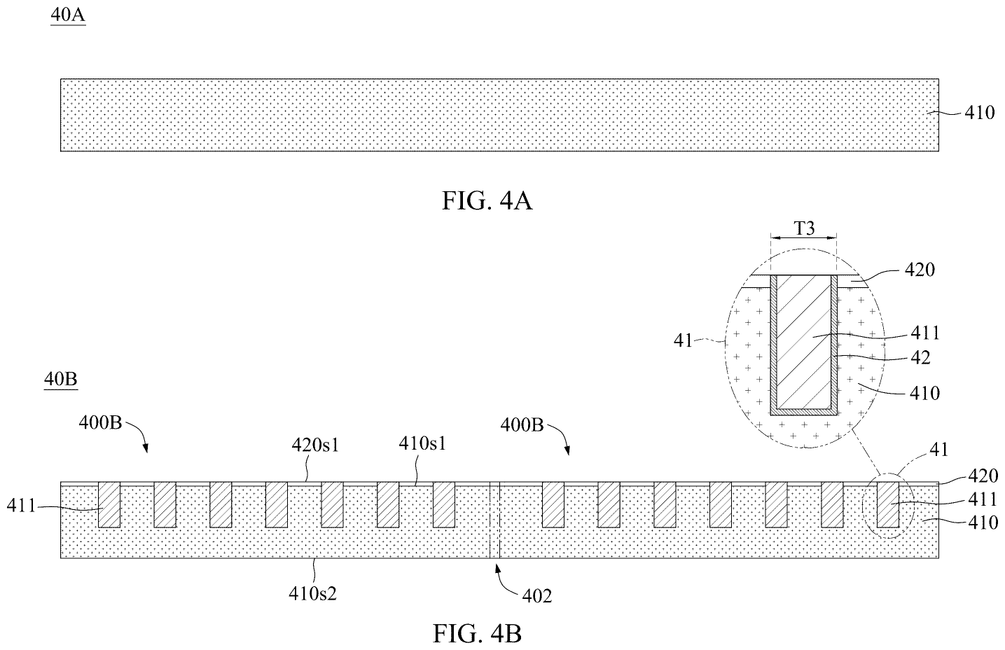

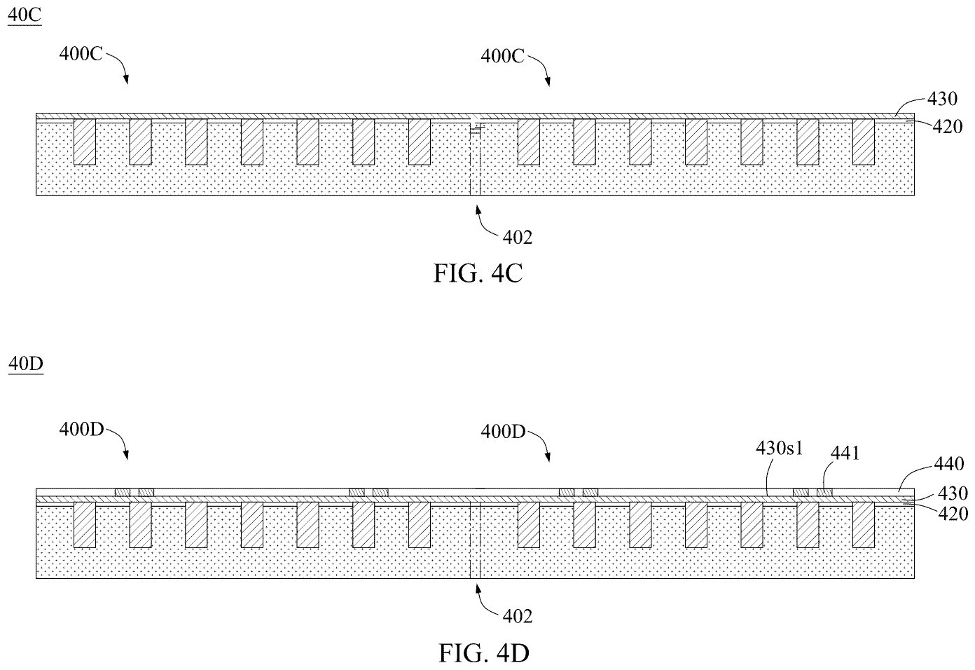

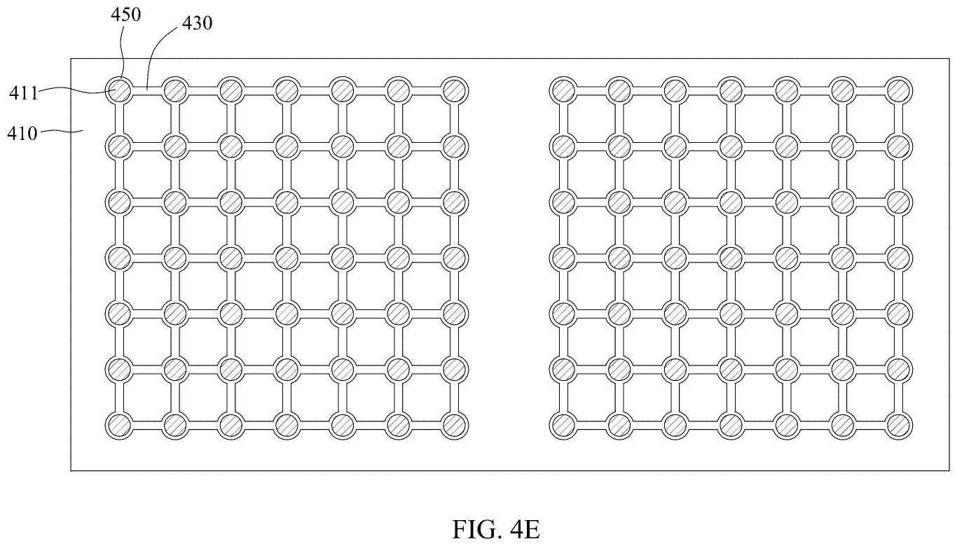

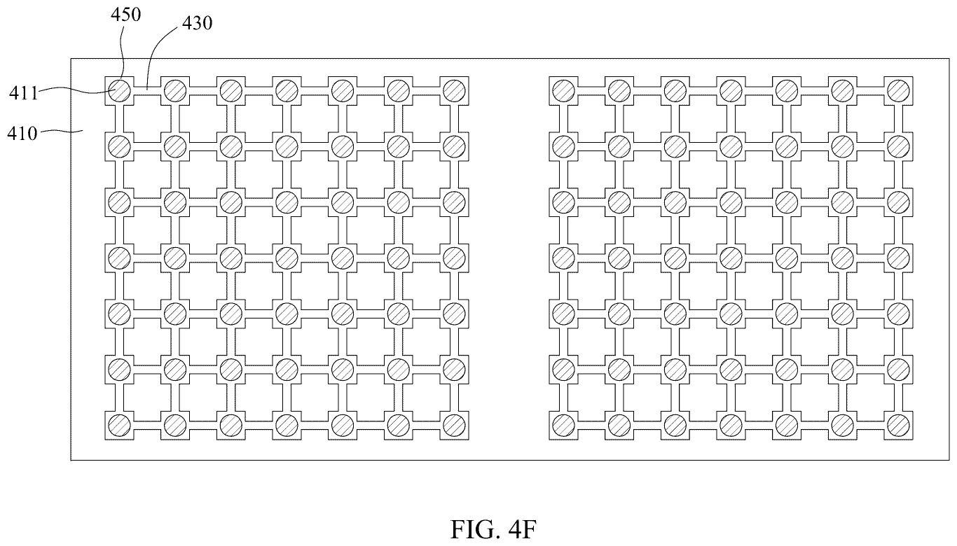

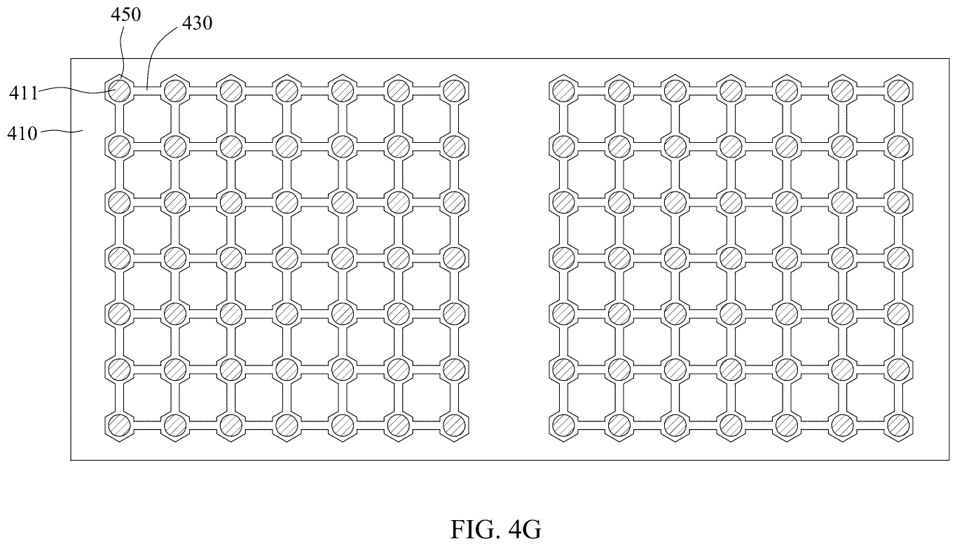

FIGS. 4A-4D are cross sections illustrating respective stages within a manufacturing process of a heat sink structure in accordance with some embodiments of the present disclosure.

FIGS. 4E to 4G are bottom views of the semiconductor structure 30E in FIG. 4D.

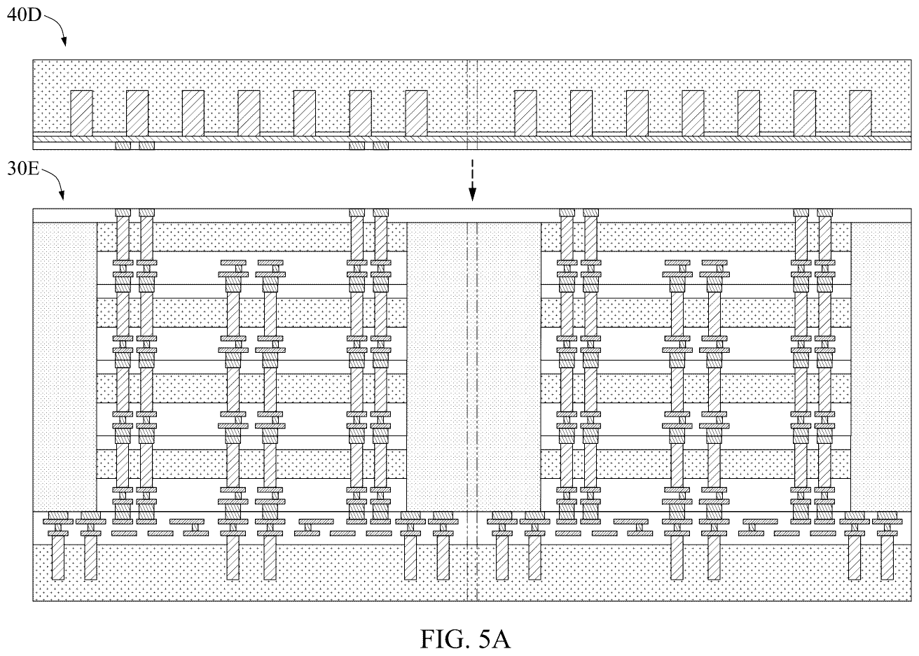

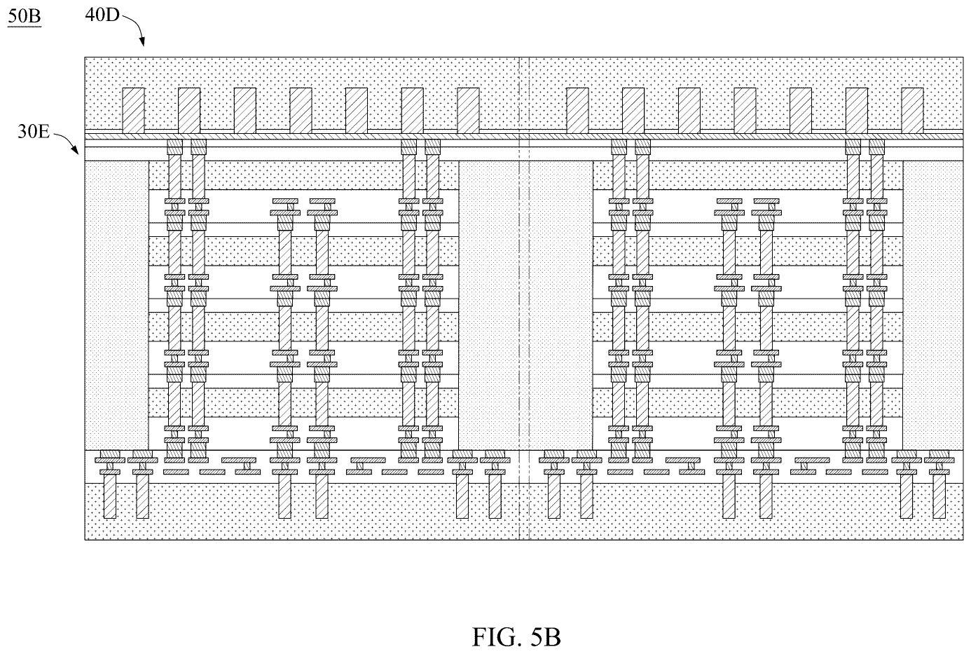

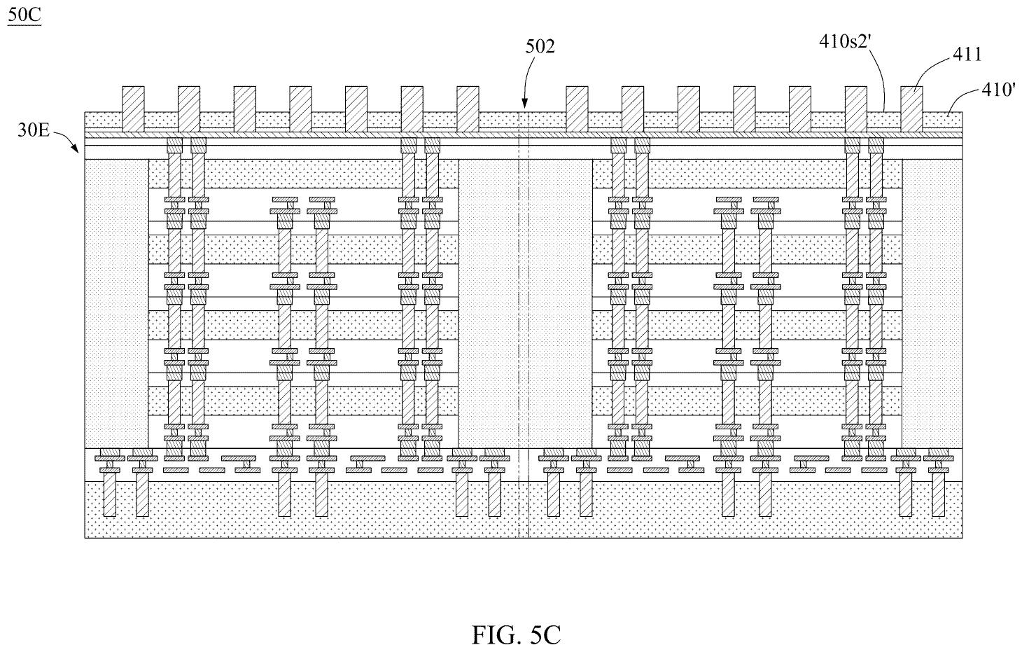

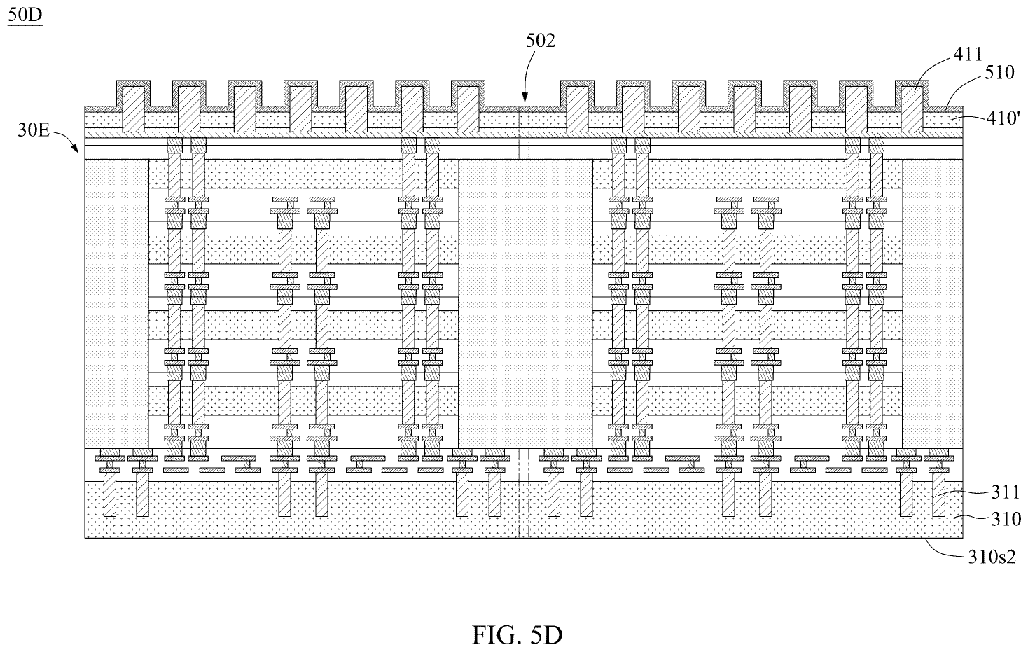

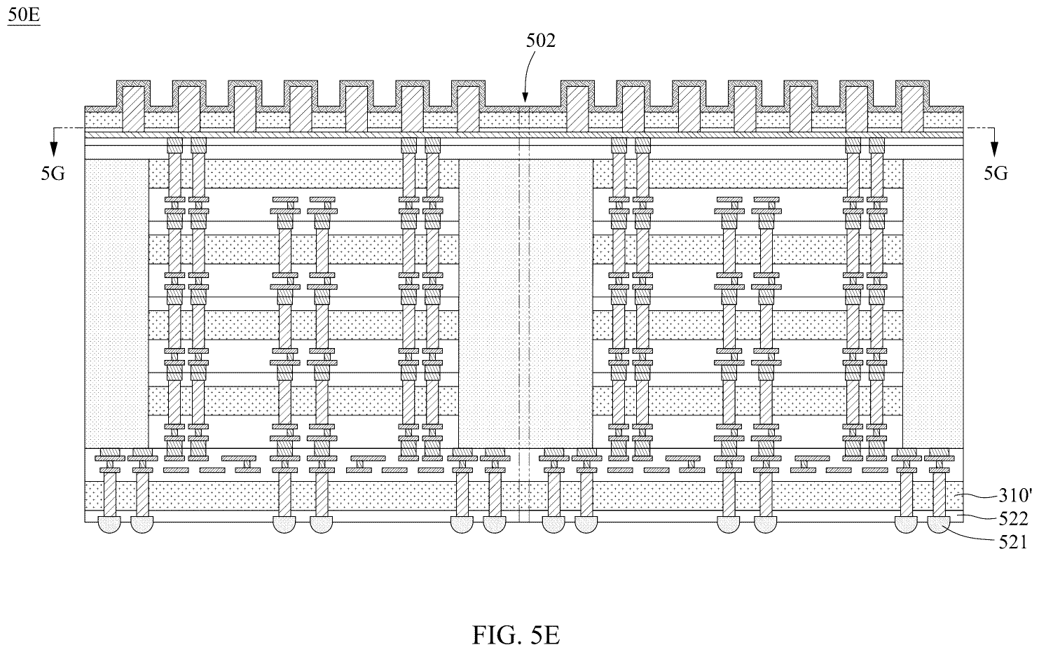

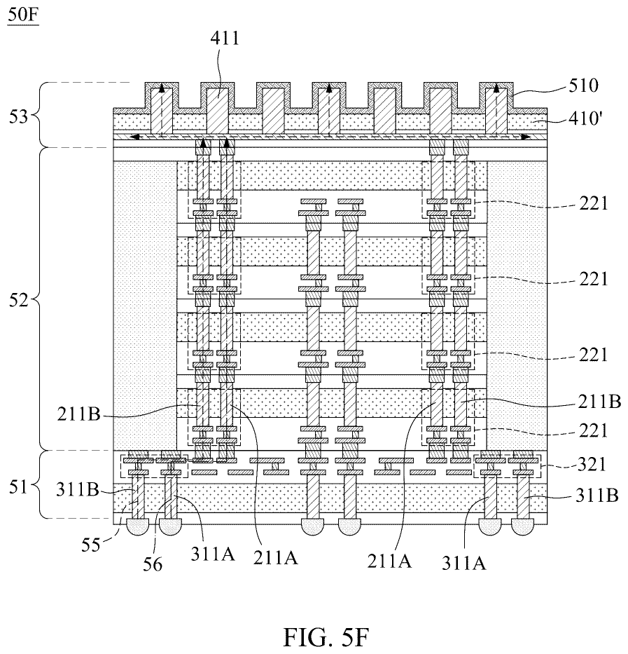

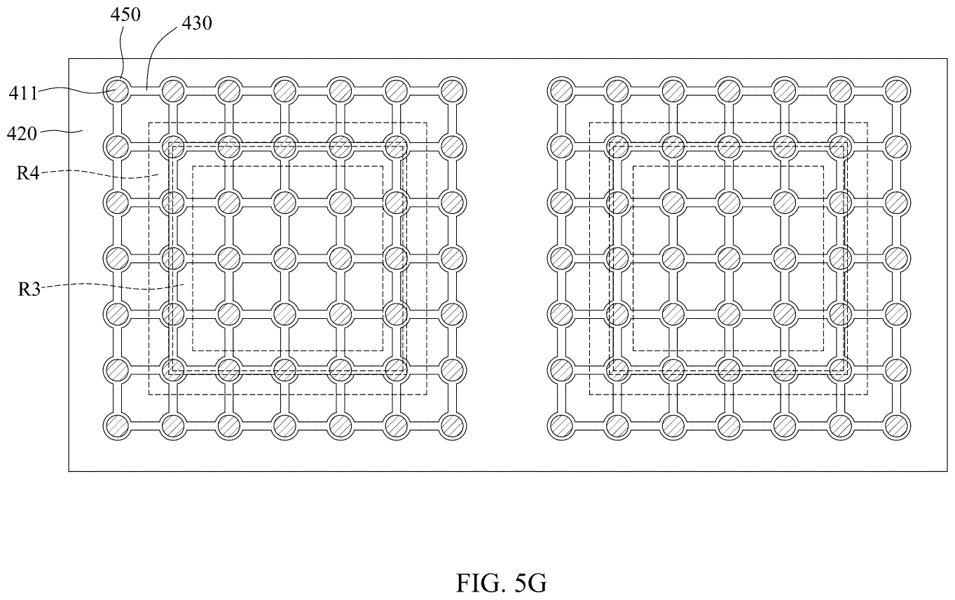

FIGS. 5A to 5F are cross sections of respective stages of forming a semiconductor structure in accordance with some embodiments of the present disclosure.

FIG. 5G is a top view of the semiconductor structure 50E from line 5G-5G in FIG. 5E.

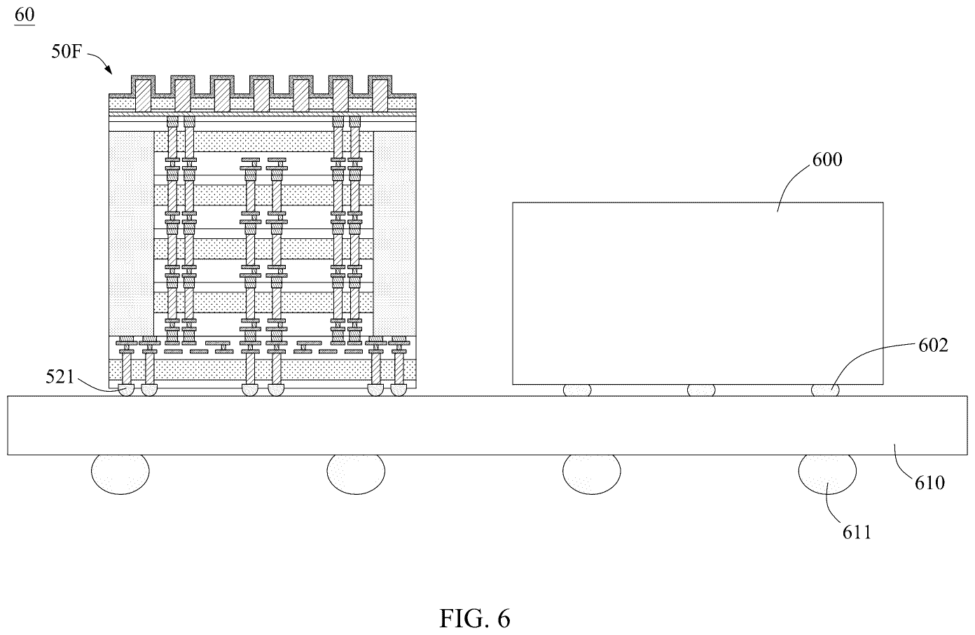

FIG. 6 is a diagram of a semiconductor package in accordance with some embodiments of the present disclosure.

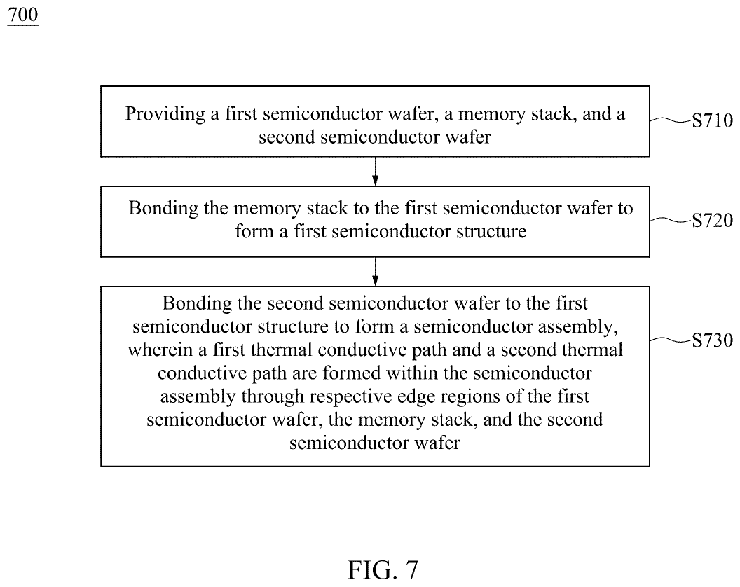

FIG. 7 is a flowchart of a method for manufacturing a semiconductor assembly in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

Reference throughout this specification to “one example” or “one embodiment” means that a particular feature, structure, or characteristic described in connection with the example is included in at least one example of the present invention. Thus, the appearances of the phrases “in one example” or “in one embodiment” in various places throughout this specification are not necessarily all referring to the same example. Furthermore, the particular features, structures, or characteristics may be combined in any suitable manner in one or more examples.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (for example, rotated 90° or at other orientations) and the spatially relative descriptors used herein interpreted accordingly. In addition, it will also be understood that when a layer is referred to as being “between” two layers, it can be the only layer between the two layers, or one or more intervening layers may also be present.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

It will be understood that when an element or layer is referred to as being “formed on,” another element or layer, it can be directly or indirectly formed on the other element or layer. That is, for example, intervening elements or layers may be present. In contrast, when an element or layer is referred to as being “directly formed on,” another element, there are no intervening elements or layers present. Other words used to describe the relationship between elements or layers should be interpreted in a like fashion (e.g., “between,” versus “directly between,” “adjacent,” versus “directly adjacent,” etc.).

FIGS. 1A and 1B are top views of different wafers in accordance with some embodiments of the present disclosure.

In some embodiments, as shown in FIG. 1, the semiconductor wafer 1 includes a plurality of semiconductor dies 110, each surrounded by a scribe line region 121, such that every two adjacent semiconductor dies 110 are separated by the scribe line region 121. The scribe line region 121 is a non-functional region on the semiconductor wafer 1. In addition, one or more dicing paths may be defined on the scribe line region 121. In some embodiments, the dicing path may be from top to bottom and from left to right, or from bottom to top and from right to left, depending on the dicing equipment.

Specifically, a semiconductor chip or die (such as a memory chip) is typically fabricated on a single semiconductor wafer along with hundreds, and in some cases thousands, of copies of the same die. The cutting needed to separate individual dies from a semiconductor wafer, a process known as “dicing” or “wafer dicing”, can be performed with a die saw (such as a diamond saw). Cuts are made along non-functional regions of semiconductor material, known as scribe lines (i.e., scribe line region 121), that separate the semiconductor dies 110 on the semiconductor wafer 1. Each of the semiconductor dies 110 may be fabricated into a semiconductor device 200D (e.g., a memory die) shown in FIG. 2E, and more details thereof will be described later.

In some embodiments, the semiconductor wafer 2 includes a plurality of semiconductor dies 130, each surrounded by a scribe line region 141, so that every two adjacent semiconductor dies 130 are separated by the scribe line region 141. The scribe line region 141 is a non-functional region on the semiconductor wafer 1. In addition, one or more dicing paths may be defined on the scribe line region 141. In some embodiments, the dicing path may be from top to bottom and from left to right, or from bottom to top and from right to left, depending on the dicing equipment.

Similarly, the semiconductor wafer 2 shown in FIG. 1B may be cut into a plurality of semiconductor dies 131 along non-functional regions of semiconductor material, known as scribe lines (i.e., scribe line region 141), that separate the semiconductor dies 130 on the semiconductor wafer 1. Each of the semiconductor dies 130 may be fabricated into a semiconductor die 300 (e.g., a memory controller IC) shown in FIG. 3A, and more details thereof will be described later.

FIGS. 2A-2E are cross sections illustrating respective stages within a manufacturing process of a semiconductor die in accordance with some embodiments of the present disclosure. Please refer to FIG. 1 and FIGS. 2A-2E.

In some embodiments, as shown in FIG. 2A, the semiconductor structure 20A (e.g., region 120 shown in FIG. 1A) includes two semiconductor dies 200A which is fabricated on the substrate 210 (e.g., semiconductor wafer 1 in FIG. 1A). In some embodiments, the substrate 210 can include single crystal substrates, semiconductor on insulator (SOI) substrates, doped silicon bulk substrate, and epitaxial film on semiconductor (EPI) substrates and the like. Further, although the various embodiments can be primarily described with respect to materials and processes compatible with silicon-based semiconductor materials (e.g., silicon and alloys of silicon with germanium and/or carbon), the present disclosure is not limited in this regard. Rather, the various embodiments can be implemented using any types of semiconductor materials.

In some embodiments, a plurality of through-silicon vias (TSVs) 211 are formed within substrate 210, as shown in FIG. 2A. A portion of each TSV 211 protrudes from a top surface 210s1 (e.g., front side) of substrate 210, and is within a dielectric layer 220. The TSVs 211 are connected to contact pads 215 through a metal layer 212, a vertical interconnect 213 (e.g., metal interconnect, such as copper), and a metal layer 214. The metal layers 212 and 214 and vertical interconnect 213 can be collectively regarded as a multilayer interconnect structure C1. The contact pads 215 may align with the top surface 220s1 of the dielectric layer 220. The dielectric layer 220 may be of one or more suitable dielectric materials such as silicon oxide, silicon nitride, low-k dielectrics such as carbon doped oxides, extremely low-k dielectrics such as porous carbon doped silicon dioxide, combinations thereof, or the like. The dielectric layer 220 may be formed through a process such as chemical vapor deposition (CVD) or thermal oxidation, although any suitable process may be utilized, and may have a thickness between about 0.5 μm and about 5 μm, such as about 9.25 kÅ.

In some embodiments, the metal layers 212 and 214 may be implemented using respective metal layers, such as silver (Ag), copper (Cu), gold (Au), aluminum-nitride (AlN), silicon-carbide (SiC), aluminum (Al), tungsten (W), zinc (Zn), or any combinations thereof. The edge regions 221 can surround one or more semiconductor elements disposed within an active region 222 (e.g., circuit region) of each semiconductor die 200A. For brevity, two TSVs 211 and their corresponding connecting structures C1 and contact pads 215 are shown in each active region 222. It should be noted that each active region 222 can include a plurality of transistors, capacitors, resistors, diodes, and the like formed in a front-end-of-line (FEOL) process.

In some embodiments, each semiconductor die 200A includes edge regions 221, and the TSVs 211 and their corresponding connecting structure C1 in the edge regions 221 may be collectively regarded as respective seal rings (e.g., first seal ring R1 and second seal ring R2 shown in FIG. 2F). The seal rings can surround the active region 222. By surrounding the active region 222 with one or more seal ring, it is possible to prevent unintended stress from propagating into the semiconductor element during chemical mechanical polishing (CMP) or dicing and thus prevent breakage of the layer in which semiconductor elements are embedded and/or delamination between adjacent layers of a stacked IC package. The seal rings (e.g., edge regions 221) can prevent stress from propagating into the semiconductor element within the active region 222. In some embodiments, the seal rings (e.g., edge regions 221) can include copper (Cu) or any other suitable materials. In some embodiments, the seal rings can each include a multilayered structure. In some embodiments, the seal rings can each include a barrier metal layer (not shown) encapsulating the backbones of the seal rings. In some embodiments, the barrier metal layer may comprise, for example, without limitation, tantalum (Ta), tantalum nitride (TaN), tungsten (W), tungsten nitride (WN), tungsten silicide (WSi), titanium (Ti), titanium nitride (TiN), and titanium silicon nitride (TiSiN).

In some embodiments, a scribe line region 200 (e.g., scribe line region 121 shown in FIG. 1A) is defined between two semiconductor dies 200A. The scribe line region 202 is a non-functional region, and one or more dicing paths may be defined on the scribe line region 202.

Referring to FIG. 2B, in some embodiments, the semiconductor dies 200A shown in FIG. 2A can be flipped, and the top surface 220s1 (e.g., front side) of the dielectric layer 220 is facing downward. Additionally, a temporary bonding process is performed on the top surface 220s1 of the dielectric layer 220 to obtain the semiconductor structure 20B including semiconductor dies 200B shown in FIG. 2B. For example, a temporary bonding layer 230 is formed on the top surface 220s1 of the dielectric layer 220. In some embodiments, the temporary bonding layer 230 includes a silicon-containing dielectric material (e.g., silicon oxide, silicon nitride, etc.) or other suitable dielectric material(s) used for bonding. An enlarged view of region 22 is illustrated. For example, lateral surfaces and the bottom surface of the TSV 211 within region 22 are surrounded by a barrier layer 216 and a liner layer 217, which are an inner layer and an outer layer, respectively. Additionally, the TSV 211 may have a width of T1 along the lateral direction. In some embodiments, the barrier layer 216 may also be regarded as a diffusion barrier, which include metal materials or conductive ceramics such as cobalt (Co), ruthenium (Ru), tantalum (Ta), tantalum nitride (TaN), indium oxide (In₂O₃), tungsten nitride (W₂N, WN, or WN₂), and titanium nitride (TiN), etc., but the present disclosure is not limited thereto. The liner layer 217 may be an oxide liner including materials such as SiO₂, but the present disclosure is not limited thereto.

Referring to FIG. 2C, in some embodiments, a backside TSV reveal process is performed on the semiconductor dies 200B shown in FIG. 2B. For example, the backside TSV reveal process can be regarded as wafer back grinding or wafer thinning, which includes a mechanical grinding process or a chemical mechanical planarization (CMP) process performed on the bottom surface 210s2 (e.g., backside) of substrate 210, such that the TSVs 211 is exposed from top surface 210s2′ of the thinned substrate 210′ to obtain semiconductor dies 200C shown in FIG. 2C. In some other embodiments, the backside TSV reveal process may include a silicon recess etching (e.g., wet etching or dry etching) process performed on the bottom surface 210s2 (e.g., backside) of substrate 210, such that the TSVs 211 is exposed from top surface 210s2′ of the thinned substrate 210′ to obtain the semiconductor structure 20C including semiconductor dies 200C shown in FIG. 2C.

Referring FIG. 2D, in some embodiments, a pad formation process is performed on the semiconductor dies 200C shown in FIG. 2C to obtain the semiconductor structure 20D including semiconductor dies 200D shown in FIG. 2D. For example, a first passivation layer 240A is first formed on the bottom surface 210s2′ of the thinned substrate 210′, and then conductive pads 241 are formed on the first passivation layer 240A at locations corresponding to the TSVs 211.

Subsequently, a second passivation layer 240B is formed on the first passivation layer 240A, and the top surface 240Bs1 of the second passivation layer 240B and the outer surfaces of conductive pads 241 are substantially coplanar. Additionally, a top view of the semiconductor dies 200D from line 2F-2F in FIG. 2D is shown in FIG. 2F. For example, the inner TSV 211 (i.e., closer to the active region 222) and its corresponding within each edge region 221 can constitute a first seal ring R1 (e.g., an inner seal ring), while the outer TSV 211 (i.e., closer to the edge of semiconductor die 200D) and its corresponding within each edge region 221 can constitute a second seal ring R2 (e.g., an outer seal ring). Since the active region 222 is surrounded by the first seal ring R1 and the second seal ring R2, it is possible to prevent unintended stress from propagating into the semiconductor element during chemical mechanical polishing (CMP) or dicing and thus prevent breakage of the layer in which semiconductor elements are embedded and/or delamination between adjacent layers of a stacked IC package. The first seal ring R1 and the second seal ring R2 can also prevent stress from propagating into the semiconductor element within the active region 222.

Referring to FIG. 2E, a debonding process and a singulation process (e.g., a wafer dicing process) are performed on the semiconductor structure shown in FIG. 2D. For example, the debonding process is first performed to debond the temporary bonding layer 230 from the dielectric layer 220, and then the singulation process is performed to cut the semiconductor structure 20D to obtain semiconductor die 200D, as shown in FIG. 2E.

FIGS. 3A-3E are cross sections of semiconductor structures within different stages for forming a 3D stacked IC package in accordance with some embodiments of the present disclosure.

In some embodiments, as shown in FIG. 3A, the semiconductor structure 30A (e.g., region 140 in FIG. 1B) includes two semiconductor dies 300 which is fabricated on the substrate 310 (e.g., semiconductor wafer 2 in FIG. 1B). In some embodiments, the substrate 310 can include single crystal substrates, semiconductor on insulator (SOI) substrates, doped silicon bulk substrate, and epitaxial film on semiconductor (EPI) substrates and the like. Further, although the various embodiments can be primarily described with respect to materials and processes compatible with silicon-based semiconductor materials (e.g., silicon and alloys of silicon with germanium and/or carbon), the present disclosure is not limited in this regard. Rather, the various embodiments can be implemented using any types of semiconductor materials.

For brevity, the semiconductor dies 300 (e.g., semiconductor dies 130 shown in FIG. 1B) have been fabricated on substrate 310 (e.g., semiconductor wafer 2 shown in FIG. 1B), but the semiconductor dies 300 have not been separated yet, as shown in FIG. 3A. Each of the semiconductor dies 300 may be a memory controller integrated circuit (IC) configured to control memory access of one or more memory chips (e.g., semiconductor die 200D) stacked thereon. In some embodiments, the semiconductor dies 300 can be fabricated in a manner similar to the semiconductor dies 200D, and thus the details thereof are not repeated here. It should be noted that when stacking the semiconductor dies 200D on the forming a three-dimensional (3D) IC package using a flip chip technique, the front side (e.g., top surface 320s1) of semiconductor dies 300 are facing upward, while the front side (e.g., top surface 220s1) of semiconductor die 200D is facing downward.

In some embodiments, a plurality of through-silicon vias (TSVs) 311 are formed within substrate 310, as shown in FIG. 3A. A portion of each TSV 311 protrudes from a top surface 310s1 (e.g., front side) of substrate 310, and is within a dielectric layer 320. The TSVs 311 are connected to conductive pads 315 through a metal layer 312, a vertical interconnect 313, and a metal layer 314. The metal layers 312 and 314 and vertical interconnect 313 can be collectively regarded as a connecting structure C2. The conductive pads 315 may align with the top surface 320s1 of the dielectric layer 320. The dielectric layer 320 may be of one or more suitable dielectric materials such as silicon oxide, silicon nitride, low-k dielectrics such as carbon doped oxides, extremely low-k dielectrics such as porous carbon doped silicon dioxide, combinations thereof, or the like. The dielectric layer 320 may be formed through a process such as chemical vapor deposition (CVD), although any suitable process may be utilized, and may have a thickness between about 0.5 μm and about 5 μm, such as about 9.25 kÅ.

In some embodiments, the metal layers 312 and 314 may be implemented using respective metal layers, such as silver (Ag), copper (Cu), gold (Au), aluminum-nitride (AIN), silicon-carbide (SiC), aluminum (Al), tungsten (W), zinc (Zn), or any combinations thereof. The edge regions 321 can surround one or more semiconductor elements disposed within an active region 322 (e.g., circuit region) of each semiconductor die 300. For brevity, two TSVs 311 and their corresponding connecting structures C2 and conductive pads 315 are shown in each active region 322. Additionally, the metal layers (e.g., the same metal layers as the metal layers 312 and 314) and vertical interconnects (e.g., the same metal layer as the vertical interconnect 313) within the active region 322 can be collectively regarded as a redistribution layer. It should be noted that the edge regions 321 are designed for heat dissipation, and they are not electrically connected to the active region 322 within each semiconductor die 300.

Similar to the semiconductor die 200D, the edge regions 321 within each semiconductor die 300 are designed as seal rings to prevent unintended stress from propagating into the semiconductor element during chemical mechanical polishing (CMP) or dicing and thus prevent breakage of the layer in which semiconductor elements are embedded and/or delamination between adjacent layers of a stacked IC package. The seal rings (e.g., edge regions 321) can prevent stress from propagating into the semiconductor element within the active region 322. In some embodiments, the seal rings (e.g., edge regions 321) can include copper (Cu) or any other suitable materials. In some embodiments, the seal rings can each include a multilayered structure. In some embodiments, the seal rings can each include a barrier metal layer (not shown) encapsulating the backbones of the seal rings. In some embodiments, the barrier metal layer may comprise, for example, without limitation, tantalum (Ta), tantalum nitride (TaN), tungsten (W), tungsten nitride (WN), tungsten silicide (WSi), titanium (Ti), titanium nitride (TiN), and titanium silicon nitride (TiSiN).

In some embodiments, a hybrid bonding technique (e.g., chip-on-wafer technique) is used to bond the semiconductor dies 200D to the semiconductor dies 300 via a bonding interface layer (not shown) to obtain the semiconductor structure 30B in FIG. 3B. The bonding interface layer may include materials such as silicon carbon nitride (SiCN), silicon oxide (SiO₂), silicon carbon (SiC), or a combination thereof, and it may have a thickness of approximately hundreds of nanometers.

Referring to FIG. 3B, an enlarged view of region 32 is illustrated. For example, lateral surfaces and the bottom surface of the TSV 311 within region 32 are surrounded by a barrier layer 316 and a liner layer 317, which are an inner layer and an outer layer, respectively. Additionally, the TSV 311 may have a width of T2 along the lateral direction. In some embodiments, the barrier layer 316 may also be regarded as a diffusion barrier, which include metal materials or conductive ceramics such as cobalt (Co), ruthenium (Ru), tantalum (Ta), tantalum nitride (TaN), indium oxide (In₂O₃), tungsten nitride (W₂N, WN, or WN₂), and titanium nitride (TiN), etc., but the present disclosure is not limited thereto. The liner layer 317 may be an oxide liner including materials such as SiO₂, but the present disclosure is not limited thereto.

Referring to FIG. 3C, in some embodiments, one or more semiconductor dies 200D are stacked on the semiconductor structure 30B to obtain the semiconductor structure 30C shown in FIG. 3C. Specifically, a memory stack 31, including a plurality of semiconductor dies 200D and a semiconductor die 200E, can be stacked on each semiconductor die 300 (e.g., a memory controller IC), and each memory stack 31 can be regarded as a high-bandwidth memory (HBM). In some embodiments, the bottom surface 310s2 (e.g., backside) of substrate 310 of the topmost semiconductor die 200E within each memory stack 31 of semiconductor structure 30C may be not thinned using a wafer grinding process or a CMP process, while the active region 222 of the topmost semiconductor die 200E within each memory stack 31 does not include TSVs 211.

Moreover, each edge region 221 in each semiconductor die 200D within the same memory stack 31 are in contact with the respective edge region 221 in the vertically neighboring semiconductor die(s) 200D, such that the vertically connected edge regions 221 are thermal conductive. Furthermore, each edge region 321 is also connected to the respective vertically connected edge regions 221 through corresponding metal layers 312 and 314 and vertical interconnect 313, thereby forming a heat conductive path. It should be noted that each heat conductive path is not electrically connected to either the active region 322 within each semiconductor die 300 or the active region 222 within each semiconductor die 200D.

Referring to FIG. 3D, in some embodiments, a molding 34 is formed to entirely encapsulate the memory stacks 31 to obtain the semiconductor structure 30D. In some embodiments, the molding 34 includes various materials, such as molding compound, molding underfill, epoxy, resin, or the like. In some embodiments, the molding 34 has a high thermal conductivity, a low moisture absorption rate and a high flexural strength.

Referring to FIG. 3E, in some embodiments, a backside TSV reveal process and a backside bonding pad formation process are performed on the semiconductor structure 30D in FIG. 3D to obtain the semiconductor structure 30E in FIG. 3E. In some embodiments, the backside TSV reveal process performed on the semiconductor structure 30D may be similar to flow shown in FIGS. 2C to 2D. For example, the backside TSV reveal process includes a mechanical grinding process or a chemical mechanical planarization (CMP) process performed on the molding 34 and the substrate 210 of the topmost semiconductor die 200E in each memory stack 31, such that the TSVs 211 of edge regions 221 are exposed. It should be noted that the bottom surface 210s2′ of the thinned substrate 210′ and the top surface 34s1 of the thinned molding 34′ are substantially coplanar. Afterwards, a first passivation layer 340A is first formed on the bottom surface 210s2′ of the thinned substrate 210′ of the topmost semiconductor dies 200D and the top surface 34s1, and then metal pads 341 (e.g., copper or other suitable metal material) are formed on the first passivation layer 340A at locations corresponding to the TSVs 211 within edge regions 221 of the topmost semiconductor dies 200D. Subsequently, a second passivation layer 340B is formed on the first passivation layer 340A, and the top surface 340Bs1 of the second passivation layer 340B and the outer surfaces of conductive pads 241 are substantially coplanar.

FIGS. 4A-4D are cross sections illustrating respective stages within a manufacturing process of a heat sink structure in accordance with some embodiments of the present disclosure.

Referring to FIG. 4A, a semiconductor substrate 410 is provided to obtain the semiconductor structure 40A. In some embodiments, the semiconductor substrate 410 can include single crystal substrates, semiconductor on insulator (SOI) substrates, doped silicon bulk substrate, and epitaxial film on semiconductor (EPI) substrates and the like. Further, although the various embodiments can be primarily described with respect to materials and processes compatible with silicon-based semiconductor materials (e.g., silicon and alloys of silicon with germanium and/or carbon), the present disclosure is not limited in this regard. Rather, the various embodiments can be implemented using any types of semiconductor materials.

Referring to FIG. 4B, a TSV forming process is performed on the semiconductor substrate 410 to form a plurality of TSVs 411 to obtain the semiconductor structure 40B. For example, a passivation layer 420 is first formed on the top surface 410s1 of substrate 410. The passivation layer 420 may be of one or more suitable dielectric materials such as silicon oxide, silicon nitride, low-k dielectrics such as carbon doped oxides, extremely low-k dielectrics such as porous carbon doped silicon dioxide, combinations thereof, or the like. The passivation layer 420 may be formed through a process such as chemical vapor deposition (CVD) or thermal oxidation, although any suitable process may be utilized. Additionally, the TSV 411 within region 41 is surrounded by a barrier layer 42, and the TSV 411 has a width T3 which is larger than the width T2 of the TSV 311 shown in FIG. 3B, and the width T1 of the TSV 211 shown in FIG. 2E. The width T2 of the TSV 311 can be different from the width T1 of the TSV 211.

In some embodiments, the barrier layer 42 may also be regarded as a diffusion barrier, which include metal materials or conductive ceramics such as cobalt (Co), ruthenium (Ru), tantalum (Ta), tantalum nitride (TaN), indium oxide (In₂O₃), tungsten nitride (W₂N, WN, or WN₂), and titanium nitride (TiN), etc., but the present disclosure is not limited thereto.

Referring to FIG. 4C, a metal layer 430 is formed on the top surface 420s1 of the passivation layer 420 to obtain the semiconductor structure 40C. In some embodiments, the metal layer 430 may be continuous across the top surface 420s1 of the passivation layer 420. Alternatively, the metal layer 430 may include respective segments on the top surface 420s1 of the passivation layer 420 for each semiconductor die 400B.

Referring to FIG. 4D, a metal pad forming process is performed. For example, metal pads 441 (e.g., copper or other suitable metal material) are formed on the top surface 430s1 of the metal layer 430 at predetermined locations, and then a passivation layer 440 is formed on the top surface 430s1 of the metal layer 430 to obtain the semiconductor structure 40D.

FIGS. 4E to 4G are bottom views of the semiconductor structure 30E in FIG. 4D. In some embodiments, the contact region 450 between the each TSV 411 and the metal layer 430 can be circle-shaped, as shown in FIG. 4E. In some other embodiments, the contact region 450 between the each TSV 411 and the metal layer 430 can be rectangular-shaped or square-shaped, as shown in FIG. 4F. In still some embodiments, the contact region 450 between the each TSV 411 and the metal layer 430 can be hexagon-shaped, as shown in FIG. 4G. It should be noted that the shape of the contact region 450 in the present disclosure is not limited to the aforementioned shapes, and other shapes can also be used depending on practical needs.

FIGS. 5A to 5F are cross sections of respective stages of forming a semiconductor structure in accordance with some embodiments of the present disclosure.

In some embodiments, as shown in FIG. 5A, a wafer-to-wafer hybrid bonding process is performed to bond the semiconductor structure 40D shown in FIG. 4D to the semiconductor structure 30E shown in FIG. 3E via a bonding interface layer (not shown), to obtain the semiconductor structure 50B shown in FIG. 5B. For example, the width of the semiconductor structure 40D may be substantially equal to that of the semiconductor structure 30E shown in FIG. 3E. When the semiconductor structure 40D is flipped vertically, the locations of the metal pads 441 may correspond to the metal pads 341 of the topmost semiconductor die 200E in the semiconductor structure 30E shown in FIG. 3E, enabling bonding between the semiconductor structure 40D shown in FIG. 4D and the semiconductor structure 30E shown in FIG. 3E.

Referring to FIG. 5C, a backside TSV reveal process is performed to expose the TSVs 411 of the semiconductor die 400D to obtain the semiconductor structure 50C shown in FIG. 5C. For example, the backside TSV reveal process includes a mechanical grinding process or a chemical mechanical planarization (CMP) process performed on the bottom surface 410s2 (e.g., backside) of substrate 410 of the semiconductor die 400D, such that the TSVs 411 is exposed from bottom surface 410s2′ of the thinned substrate 410′ to obtain the semiconductor structure 50C shown in FIG. 5C.

Referring to FIG. 5D, a film deposition process is performed on the semiconductor structure 50C shown in FIG. 5C to obtain the semiconductor structure 50D shown in FIG. 5D. For example, a carbon film 510 is formed on the exposed TSVs 411 and the thinned substrate 410′ using a chemical vapor deposition (CVD) process or a physical vapor deposition (PVD) process. For example, the carbon film 510 can be used for heat dissipation.

Referring to FIG. 5E, a backside TSV reveal process and a backside bump forming process are performed on the semiconductor structure 50D shown in FIG. 5D to obtain the semiconductor structure 50E shown in FIG. 5E. For example, the backside TSV reveal process is performed on the bottom surface 310s2 of substrate 310 of the semiconductor structure 50D to expose the TSVs 311. Subsequently, a plurality of bumps 521 are formed on the exposed TSVs 311, and then a passivation layer 522 is formed on the bottom surface of the thinned substrate 310′ to obtain the semiconductor structure 50E shown in FIG. 5E. A top view of the semiconductor structure 50E from line 5G-5G is shown in FIG. 5G. As can be seen from FIG. 5G, the seal rings R3 and R4 can be regarded as the edge regions of each semiconductor dies within the 3D memory stack 52 shown in FIG. 5F.

Referring to FIG. 5F, a singulation process is performed on the semiconductor structure 50E shown in FIG. 5E to obtain the semiconductor assembly 50F shown in FIG. 5F. For example, the semiconductor structure 50E is cut along the scribe region 502, and two semiconductor structures 50E are obtained. Specifically, the semiconductor assembly 50F shown in FIG. 5F is a 3D IC package including a memory controller IC 51 (e.g., semiconductor die 300E), a 3D memory stack 52 (e.g., stack of semiconductor dies 200D and 200E), and a heat sink structure 53 (e.g., semiconductor structure 40D). The heat generated by the semiconductor structure 50E can be dissipated by the heat sink structure 53 along the thermal conductive path 55 through the memory controller IC 51, 3D memory stack 52, and heat sink structure 53. Specifically, the thermal conductive path 55 is formed along the edge regions of the memory controller IC 51, 3D memory stack 52, and heat sink structure 53, which constitute seal rings of respective semiconductor dies (e.g., seal rings R1 and R2 shown in 2F). Additionally, as described above, the edge regions semiconductor dies are not electrically connected, but thermal conductive, to the active regions within respective semiconductor dies. As such, the heat generated by the active region can be transmitted to the edge regions of respective semiconductor dies, and dissipated by the heat sink structure 53 along the thermal conductive path 55.

It should be noted that the heat sink structure 53 includes a plurality of protrusions, each including a respective TSV 411 covered by the carbon film 510. Additionally, the semiconductor substrate 410 of the heat sink structure 53 can be used as a heat conductive board. Furthermore, the width of the TSVs 411 is greater than the width of the TSVs 211 and 311, such that the heat generated by the semiconductor structure 50E can be effectively dissipated by the heat sink structure 53 through the TSVs 411 and the carbon film 510.

FIG. 6 is a diagram of a semiconductor package in accordance with some embodiments of the present disclosure.

In some embodiments, the semiconductor assembly 50F shown in FIG. 5F and an integrated circuit 600 can be disposed on a printed circuit board 610 through their respective bumps 521 and 602 to obtain the semiconductor package 60 shown in FIG. 6. For example, the integrated circuit 600 may be a processor such as a central processing unit (CPU), a digital signal processor (DSP), an image signal processor (ISP), a neural processing unit (NPU), etc. Alternatively, the integrated circuit 600 may be a logic integrated circuit including one or more logic circuits to perform designated functions. Additionally, the printed circuit board 610 includes a plurality of solder balls 611 disposed thereon, allowing the semiconductor package 60 to electrically connect to other semiconductor packages or integrated circuits. Additionally, the semiconductor assembly 50F is electrically connected to the integrated circuit 600 through an interposer (not shown) within the printed circuit board 610. Accordingly, the semiconductor package 60 can be regarded as a CoWoS (chip-on-wafer & wafer-on-substrate) package.

FIG. 7 is a flowchart of a method for manufacturing a semiconductor assembly in accordance with some embodiments of the present disclosure. Please refer to FIG. 5F and FIG. 7.

In step S710, a first semiconductor wafer, a memory stack, and a second semiconductor wafer are provided. For example, the first semiconductor wafer may refer to memory controller IC 51 shown in FIG. 5F, which includes a plurality of semiconductor dies 300 shown in FIG. 3A. The memory stack may refer to the memory stack 52 shown in FIG. 5F, which includes semiconductor dies 200D and 200E shown in FIG. 3E. The second semiconductor wafer may refer to heat sink structure 53 shown in FIG. 5F, which includes the semiconductor structure 40D shown in FIG. 4D.

In step S720, the memory stack is bonded to the first semiconductor wafer to form a first semiconductor structure. In some embodiments, a flip chip hybrid bonding process can be performed to bond the memory stack to the first semiconductor wafer via a bonding interface layer, as shown in FIG. 3B.

In step S730, the second semiconductor wafer is bonded to the first semiconductor structure to form a semiconductor assembly, wherein a first thermal conductive path and a second thermal conductive path are formed within the semiconductor assembly through respective edge regions of the first semiconductor wafer, the memory stack, and the second semiconductor wafer. In some embodiments, a flip chip hybrid bonding process can be performed

In an aspect of the present disclosure, a semiconductor assembly is provided, which includes a first semiconductor wafer, a memory stack, and a second semiconductor wafer. The memory stack is bonded to the first semiconductor wafer, and the second semiconductor wafer is bonded to the memory stack. The second semiconductor wafer includes a heat sink structure configured to dissipate heat generated by the first semiconductor wafer and the memory stack through a first thermal conductive path and a second thermal conductive path within the semiconductor assembly.

In some embodiments, the first semiconductor wafer comprises a first semiconductor die configured to function as a memory controller integrated circuit.

In some embodiments, the memory stack comprises a plurality of memory dies stacked vertically.

In some embodiments, each of the first semiconductor die and the memory dies comprises an active region and edge regions which surround the active region and is non-electrically connected to the active region.

In some embodiments, each edge region within each of the first semiconductor die and the memory dies comprises a first through-silicon via (TSV) and a second TSV, and the first thermal conductive path and the second thermal conductive path are established along the first TSV and the second TSV of each edge region within each of the first semiconductor die and the memory dies, respectively.

In some embodiments, the heat sink structure comprises a silicon substrate, and a plurality of third TSVs which are formed on the silicon substrate and protrudes from a top surface of the silicon substrate.

In some embodiments, the third TSVs and the top surface of the silicon substrate are covered by a carbon film.

In some embodiments, a first width of each third TSV is greater than a second width of the first TSV and the second TSV in each edge region within each of the first semiconductor die and the memory dies.

In some embodiments, the first TSV in each edge region is closer to the active region within each of the first semiconductor die and the memory dies. The second TSV in each region is farther from the active region. The first TSVs and the second TSVs in the edge regions within each of the first semiconductor die and the memory dies constitute a first seal ring and a second seal ring, respectively.

In some embodiments, each third TSV is surrounded by a first barrier layer.

In some embodiments, each of the first TSVs and the second TSVs are surrounded by a respective second barrier layer and a respective liner layer.

In some embodiments, a metal layer is formed on a bottom surface of the silicon substrate, and intersects with each third TSV.

In some embodiments, a contact region between each third TSV and the metal layer is circle-shape, rectangular-shaped, or hexagon-shaped.

In some embodiments, the memory stack is encapsulated by a molding.

In some embodiments, the semiconductor assembly and an integrated circuit are disposed on a printed circuit board to form a semiconductor package.

In another aspect of the present disclosure, a semiconductor assembly is provided, which includes a first semiconductor structure; and a second semiconductor structure, bonded to the first semiconductor structure. The second semiconductor structure comprises a silicon substrate and a plurality of heat dissipating components formed on the silicon substrate to dissipate heat generated by the first semiconductor structure.

In some embodiments, the first semiconductor structure comprises a first semiconductor die and a memory stack bonded to the first semiconductor die, and the first semiconductor die is configured to function as a memory controller integrated circuit for controlling memory access of the memory stack.

In some embodiments, the memory stack is a high-bandwidth memory.

In some embodiments, the memory stack comprises a plurality of memory dies. Each of the first semiconductor die and the memory dies comprises an active region and edge regions which surround the active region and is non-electrically connected to the active region.

In some embodiments, each edge region within each of the first semiconductor die and the memory dies comprises a first through-silicon via (TSV) and a second TSV, and a first thermal conductive path and a second thermal conductive path are established along the first TSV and the second TSV of each edge region within each of the first semiconductor die and the memory dies, respectively.

In some embodiments, the heat dissipating components comprise a plurality of third TSVs which are formed on the silicon substrate and protrudes from a top surface of the silicon substrate.

In some embodiments, the third TSVs and the top surface of the silicon substrate are covered by a carbon film.

In some embodiments, a first width of each third TSV is greater than a second width of the first TSV and the second TSV in each edge region within each of the first semiconductor die and the memory dies.

In some embodiments, the first TSV in each edge region is closer to the active region within each of the first semiconductor die and the memory dies. The second TSV in each region is farther from the active region. The first TSVs and the second TSVs in the edge regions within each of the first semiconductor die and the memory dies constitute a first seal ring and a second seal ring, respectively.

In some embodiments, each third TSV is surrounded by a first barrier layer. Each of the first TSVs and the second TSVs are surrounded by a respective second barrier layer and a respective liner layer.

In yet another aspect of the present disclosure, a method is provided, which includes the following steps: providing a first semiconductor wafer, a memory stack, and a second semiconductor wafer; bonding the memory stack to the first semiconductor wafer to form a first semiconductor structure; and bonding the second semiconductor wafer to the first semiconductor structure to form a semiconductor assembly, wherein a first thermal conductive path and a second thermal conductive path are formed within the semiconductor assembly through respective edge regions of the first semiconductor wafer, the memory stack, and the second semiconductor wafer.

In some embodiments, the first semiconductor wafer comprises a first semiconductor die. The memory stack comprises a plurality of memory dies. Each of the first semiconductor die and the memory dies comprises an active region and edge regions which surround the active region and is non-electrically connected to the active region.

In some embodiments, each edge region within each of the first semiconductor die and the memory dies comprises a first through-silicon via (TSV) and a second TSV, and the first thermal conductive path and the second thermal conductive path are established along the first TSV and the second TSV of each edge region within each of the first semiconductor die and the one or more memory dies, respectively.

In some embodiments, the second semiconductor wafer comprises a silicon substrate, and a plurality of third TSVs which are formed on the silicon substrate and protrudes from a top surface of the silicon substrate.

In some embodiments, the third TSVs and the top surface of the silicon substrate are covered by a carbon film.

Although the present disclosure and its advantages have been described in detail, it should be understood that various changes, substitutions and alterations can be made herein without departing from the spirit and scope of the disclosure as defined by the appended claims.

For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed is:

1. A semiconductor assembly, comprising:
a first semiconductor structure; and
a second semiconductor structure, bonded to the first semiconductor structure, wherein the second semiconductor structure comprises a silicon substrate and a plurality of heat dissipating components formed on the silicon substrate to dissipate heat generated by the first semiconductor structure.

2. The semiconductor assembly of claim 1, wherein the first semiconductor structure comprises a first semiconductor die and a memory stack bonded to the first semiconductor die, and the first semiconductor die is configured to function as a memory controller integrated circuit for controlling memory access of the memory stack.

3. The semiconductor assembly of claim 2, wherein the memory stack is a high-bandwidth memory.

4. The semiconductor assembly of claim 2, wherein:
the memory stack comprises a plurality of memory dies; and
each of the first semiconductor die and the memory dies comprises an active region and edge regions which surround the active region and is non-electrically connected to the active region.

5. The semiconductor assembly of claim 4, wherein each edge region within each of the first semiconductor die and the memory dies comprises a first through-silicon via (TSV) and a second TSV, and a first thermal conductive path and a second thermal conductive path are established along the first TSV and the second TSV of each edge region within each of the first semiconductor die and the memory dies, respectively.

6. The semiconductor assembly of claim 5, wherein the heat dissipating components comprise a plurality of third TSVs which are formed on the silicon substrate and protrudes from a bottom surface of the silicon substrate.

7. The semiconductor assembly of claim 6, wherein the third TSVs and the bottom surface of the silicon substrate are covered by a carbon film.

8. The semiconductor assembly of claim 7, wherein a first width of each third TSV is greater than a second width of the first TSV and a third width of the second TSV in each edge region within each of the first semiconductor die and the memory dies.

9. The semiconductor assembly of claim 8, wherein:
the first TSV in each edge region is closer to the active region within each of the first semiconductor die and the memory dies;
the second TSV in each region is farther from the active region; and
the first TSVs and the second TSVs in the edge regions within each of the first semiconductor die and the memory dies constitute a first seal ring and a second seal ring, respectively.

10. The semiconductor assembly of claim 8, wherein:
each third TSV is surrounded by a first barrier layer; and
each of the first TSVs and the second TSVs are surrounded by a respective second barrier layer and a respective liner layer.
